(19) United States
(12) Patent Application Publication
(10) Pub. No.: US 2007/0121395 A1
(43) Pub. Date: May 31, 2007

(54) Device and Method of Controlling Source Driver

(76) Inventors: Sang-hun Kim, Seoul (KR); Byung-hun Han, Seoul (KR); Kyung-myun Kim, Seoul (KR)

Correspondence Address: Frank Chau, Esq.;F. CHAU & ASSOCIATES, LLC, 130 Woodbury Road, Woodbury, NY, 11797, US

(21) Appl. No.: 11/560,035

(22) Filed: Nov. 15, 2006

(30) Foreign Application Priority Data
Nov. 23, 2005 (KR) 10-2005-0112317

(51) Int. Cl. G11C 7/00

(52) U.S. Cl. 365/195

(57) ABSTRACT

A source driver control device and method. The source driver control device includes a memory, a first write controller, a second write controller and a write clock signal generator. The memory receives display data corresponding to an image and stores the display data in response to a write clock signal. The first write controller generates a first write enable signal in response to a vertical back porch and a horizontal back porch. The second write controller generates a second write enable signal, which is enabled for each write cycle of storing the display data in the memory, in response to the first write enable signal. The write clock signal generator generates the write clock signal in a period in which the second write enable signal is enabled. The write cycle corresponds to a multiple of a reference write cycle. The source driver control device and method can reduce power consumed when the display data is written in the memory.

### CROSS-REFERENCE TO RELATED PATENT APPLICATION

This application claims priority to Korean Patent Application No. 10-2005-0112317, filed on Nov. 23, 1005, in the Korean intellectual Property Office, the disclosure of which is incorporated by reference herein in its entirety.

### BACKGROUND OF THE INVENTION

1. Technical Field

The present invention relates to a source driver, and more particularly, to a device and method for controlling a source driver.

2. Discussion of the Related Art

FIG. 1 is a block diagram of a general display device 100. Referring to FIG. 1, the display device 100 includes a panel 110, a gate driver block 120, a source driver block 130 and a source driver controller 140. The source driver controller 140 includes a memory 145 and the source driver block 130 includes a plurality of source driver (not shown). shown) of the panel 110 in response to the control signals output from the source driver controller 140.

A general moving image includes a plurality of frames sequentially displayed. The frames are composed of display data. In a general moving image, two or four continuous frames have the same display data DATA. The conventional source driver controller 140 sequentially stores display data DATA of all frames in the memory 145. Thus, when the display deice 100 including the conventional source driver controller 140 displays the general moving image, the same display data DATA is repeatedly stored in the memory 145 for every two or four continuous frames.

The repeated storage of the display data DATA in the memory 145 wastes power. Particularly, the waste of power becomes a serious problem in an RGB interface mode of displaying a moving image.

The source driver controller 140 stores the display data DATA in the memory 145 in response to a predetermined write enable signal. However, the write enable signal is not provided to the source driver controller in an RGB sync interface mode. Accordingly, the conventional source driver controller 140 should receive the write enable signal from an external device when connected to an RGB sync interface.

### SUMMARY OF THE INVENTION

Exemplary embodiments of the present invention provide a source driver control device and a method of writing display data in a memory without receiving a write enable signal from an external device.

According to an exemplary embodiment of the present invention, a source driver control device including a memory, a first write controller, a second write controller and a write clock signal generator are provided.

The memory receives display data corresponding to an image and stores the display data in response to a write clock signal. The first write controller generates a first write enable signal in response to a vertical back porch and a horizontal back porch. The second write controller generates a second write enable signal, which is enabled for each write cycle of storing the display data in the memory, in response to the first write enable signal. The write clock signal generator generates the write clock signal in a period in which the second write enable signal is enabled. The write cycle corresponds to a multiple of a reference write cycle.

The first write controller may include a line counter, a pixel counter and a first write enable signal generator. The line counter counts pulses of a horizontal synchronization signal and outputs the counted result as line counting values. The pixel counter counts pulses of a system clock signal and outputs the counted result as pixel counting values. The first write enable signal generator generates the first write enable signal in response to a line counting value corresponding to the vertical back porch and a pixel counting value corresponding to the horizontal back porch.

The first write enable signal generator may receive the line counting value corresponding to the vertical back porch, and then enable the first write enable signal upon receiving the pixel counting value corresponding to the horizontal back porch.

The first write enable signal generator may drive the pixel counter upon receiving the line counting value corresponding to the vertical back porch, receive the pixel counting values from the pixel counter, and enable the first write enable signal upon receiving the pixel counting value corresponding to the horizontal back porch.

The first write enable signal generator may hold the first write enable signal at the enabled level during an effective data period and disable the first write enable signal upon receiving a line counting value corresponding to a vertical front porch.

The second write controller may include a frame counter and a second write enable signal generator. The frame counter counts pulses of a vertical synchronization signal and outputs the counted result as a frame count. The second write enable signal generator generates the second write enable signal in response to a write cycle select signal for selecting the write cycle and the frame count.

The second write enable signal generator may generate the second write enable signal when receiving the frame count corresponding to the write cycle select signal.

According to an exemplary embodiment of the present invention, a source driver control device including a memory and a memory controller is provided.

The memory receives display data corresponding to an image and stores the display data in response to a write cycle of storing the display data in the memory. The write cycle corresponds to a multiple of a reference write cycle.

The memory controller includes a write enable signal generator and a write clock signal generator. The write enable signal generator generates a write enable signal, which is enabled for each write cycle, in response to a write cycle select signal for selecting the write cycle. The write clock signal generator generates the write clock signal in a period in which the write enable signal is enables.

According to an exemplary embodiment of the present invention, a method of controlling a source driver comprising generating a first write enable signal, generating a second write enable signal, generating a write clock signal, and storing display data is provided.

The first write enable signal is generated in response to a vertical back porch and a horizontal back porch. The second write enable signal, which is enabled for each write cycle corresponding to a multiple of a reference write cycle, is generated in a period in which the second write enable signal is enabled. In the storing display data, display data corresponding to an image is received and stored in response to the write clock signal.

### BRIEF DESCRIPTION OF THE DRAWINGS

The above and other features of the exemplary embodiments of the present invention will become more apparent by description with reference to the attached drawings in which:

FIG. 1 is a block diagram of a conventional display device;

FIG. 2 is a block diagram of a source driver control device according to an exemplary embodiment of the present invention;

FIG. 3 is a timing diagram for explaining the operation of the source driver control device of FIG. 2;

FIG. 4 is a timing diagram for explaining an operation of generating a first write enable signal in the source driver control device of FIG. 2; and

FIG. 5 is a flow chart showing a method of controlling a source driver according to an exemplary embodiment of the present invention.

### DETAILED DESCRIPTION OF THE EXEMPLARY EMBODIMENTS

The present invention will now be described more fully with reference to the accompanying drawings, in which exemplary embodiments of the invention are shown. The invention should not be construed as being limited to the exemplary embodiments set forth herein. Throughout the drawings, like reference numerals refer to like elements.

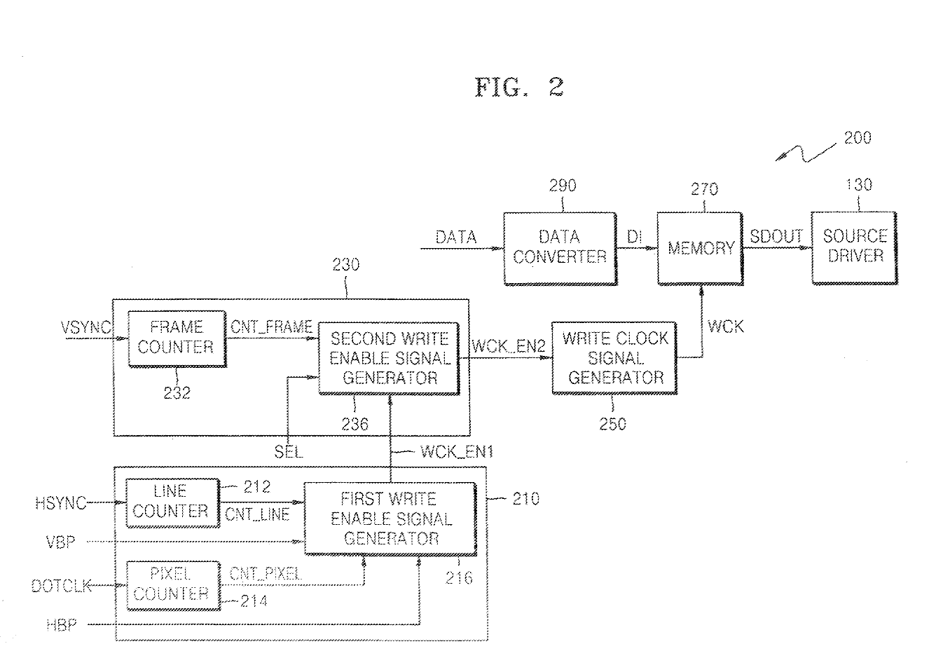

FIG. 2 is a block diagram of a source driver control device 200 according to an exemplary embodiment of the present invention. Referring to FIG.2, the source driver control device 200 includes a memory 270, a first write controller 210, a second write controller 230, and a write clock signal generator 250. FIG. 2 also illustrates a source driver 130 to more conveniently explain the exemplary embodiments.

The memory 270 receives display data DATA and store the display data in response to a write clock signal WCK. The memory 270 outputs the stored display data DATA to the source driver 130 in response to a scan clock signal SCK.

The first write controller 210 generates a first write enable signal WCK_EN1 in response to vertical back porch (VBP) and horizontal back porch (HBP). The second write controller 230 generates a second write enable signal WCK_EN2, which is enabled for each write cycle, in response to the first write enable signal WCK_EN1. The write clock signal generator 250 generates the write clock signal WCK in a period in which the second write enable signal WCK_EN2 is enabled.

The first write enable signal WCK_EN1 may be enabled for each reference write cycle and the second write enable signal WCK_EN2 may be enabled for each write cycle.

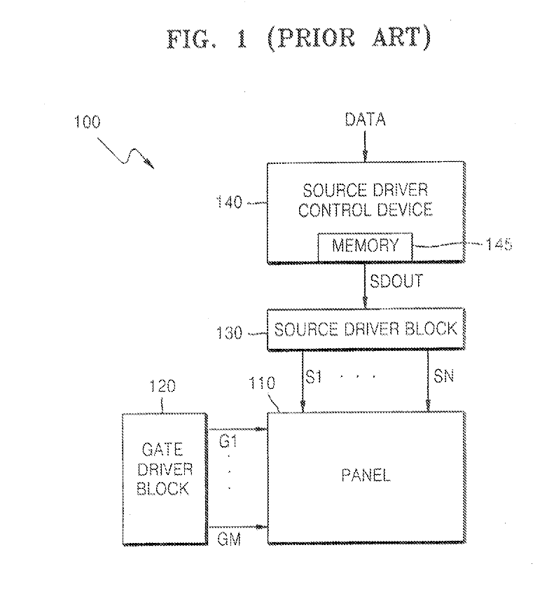

The reference write cycle is a cycle in which the conventional display device 100 (refer to FIG. 1) stores display data in a memory or displays the data. The display device display 60 frames per second, for example, the reference write cycle is 1/60 seconds. The write cycle is a cycle in which the source driver control device 200, according to exemplary embodiments of the present invention, stores the display data DATA in the memory 270. The write cycle may correspond to a multiple of the reference write cycle

When a moving image in which display data is changed for every two frames is displayed, the write cycle of the source driver control device 299, according to exemplary embodiments of the present invention, can be 1/30 second (half the reference write cycle). When a moving image in which display data is changed for each frame is displayed, the write cycle can be 1/60 second (identical to the reference write cycle). That is, the source driver control device 200 according to the present invention can select the write cycle of storing the display data DATA in the memory 270.

The first write controller 210 includes a line counter 212, a pixel counter 214 and a first write enable signal generator 216. The line counter 212 counts pulses of a horizontal synchronization signal HSYNC and outputs the counted result as line counting values CNT_LINE. The pixel counter 214 counts pulses of a system clock signal DOTCLK and outputs the counted result as pixel counting values CNT_PIXEL. The first write enable signal generator 216 generates the first write enable signal WCK_EN1 in response to the line counting values CNT_LINE and the pixel counting values CNT_PIXEL. For example, the first write enable signal generator 216 enables the first write enable signal WCK_EN1 when it receives a line counting value CNT_LINE, corresponding to the VBP, and a pixel counting value CNT_PIXEL, corresponding to the HBP, while receiving the line counting values CNT_LINE and the pixel counting values CNT_PIXEL which increases sequentially.

The second write controller 230 includes a frame counter 232 and a second write enable signal generator 236. The frame counter 232 counts pulses of a vertical synchronization signal VSYNC and outputs the counted result as frame counts CNT_FRAME. The second write enable signal generator 236 outputs the second write enable signal WCK_EN2 in response to a write cycle select signal SEL and the frame count CNT_FRAME. For example, the second write enable signal generator 236 enables the second write enable signal WCK_EN2 when it receives a frame count CNT_FRAME, corresponding to the write cycle select signal SEL for selecting a write cycle, while receiving the frame counts CNT_FRAME which increases sequentially. The write clock signal generator 250 enables the write clock signal WCK in a period in which the second write enable signal WCK_CN2 is enabled.

The source driver control device 200 according to exemplary embodiments of the present invention may further include a data converter 290. The data converter 290 receives the display data DATA and converts the display data DATA into converted display data DI. For example, the data converter 290 changes the sequence of the display data DATA and outputs the converted display data DI. For example, the memory 270 receives and stores the converted display data DI instead of the display data DATA.

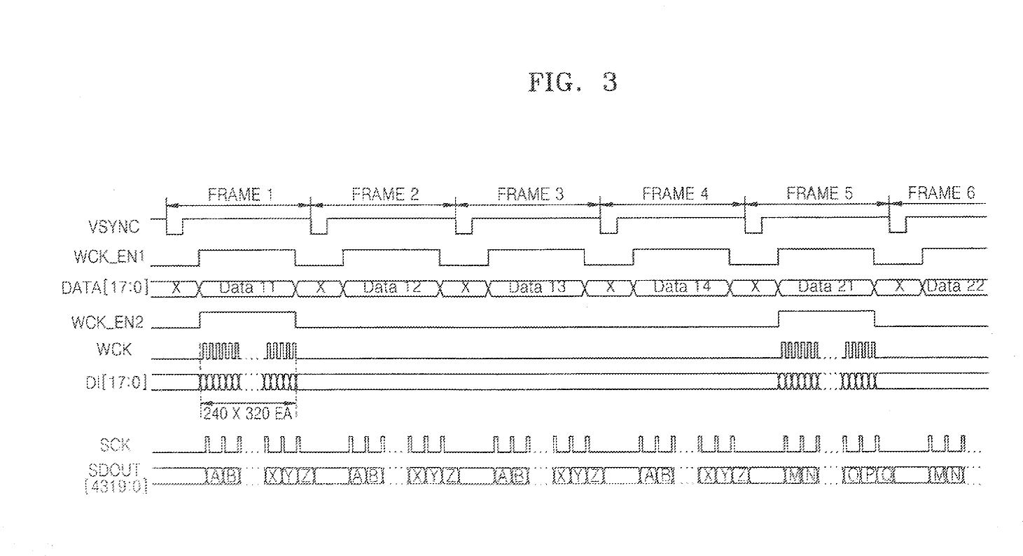

FIG. 3 is a timing diagram for explaining the operation of the source driver control device 200 of FIG. 2. FIG. 3 shows an operation of the source driver control device 200 when a moving image in which display data is changed for every four frames is displayed. For example, display data DATA11, DATA12, DATA13 and DATA14 of the first, second, third and fourth frames FRAME1, FRAME2, FRAME3 and FRAME4 have the same value.

The operation of the source driver control device 200 according to an exemplary embodiment of the present invention will now be explained in detail with reference to FIGS. 2 and 3.

The vertical synchronization signal VSYNC is enabled to a low level for each frame. While the vertical synchronization signal VSYNC is enabled to a low level in FIG. 3, it can be enabled to a high level.

The frame counter 232 counts the number of times the vertical synchronization signal VSYNC is enabled and outputs the frame count CNT_FRAME. As described above, the vertical synchronization signal VSYNC is enabled for each frame, and thus the number of times the vertical synchronization signal VSYNC is enabled is equal to the frame count CNT_FRAME.

The second write enable signal generator 236 enables the second write enable signal WCK_EN2 when it receives a frame count CNT_FRAME corresponding to the write cycle select signal SEL. The second write enable signal generator 236 enables the second write enable signal WCL_EN2 in synchronization with part of a plurality of enabling periods of the first write enable signal WCL_EN1. The first write enable signal WCK_EN1 is enabled for each frame.

When a moving image in which display data is changed for every four frames is displayed, for example, the write cycle select signal SEL has a value corresponding to four frames. In this case, the second write enable signal generator 236 enables the second write enable signal WCK_EN2 whenever the received frame count CNT_FRAME becomes a multiple of 4. Referring to FIG. 3, the second write enable signal WCK_EN2 is enabled in the first frame FRAME1 and the fifth frame FRAME5.

The write clock signal generator 250 generates the write clock signal WCK in periods in which the second write enable signal WCK_EN2 is enabled. The data converter 290 receives display data DATA[17:1] and stores data DI[17:0]. The memory 270 receives the converted display data DI[17:1] and stores the converted display data DI[17:1] to the source driver 130 memory 270 outputs the stored converted display data DI[17:0] to the source driver 130 in response to the scan clock signal SCK.

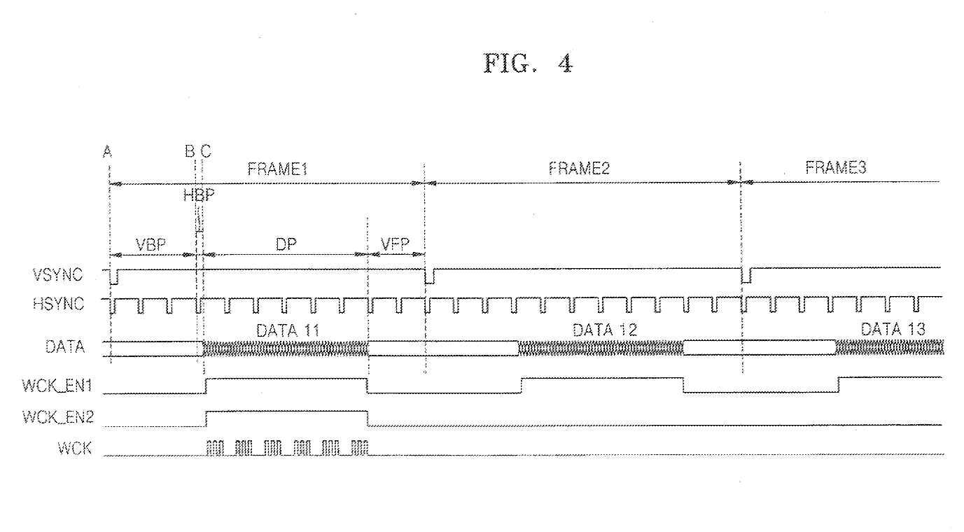

FIG. 4 is a timing diagram for explaining the operation of generating the first write enable signal. The operation of the first write controller 210 for generating the first write enable signal WCK_EN1 will now be explained in detail with reference to FIGS. 2 and 4.

The vertical synchronization signal VSYNC and the horizontal synchronization signal HSYNC are enabled to a low level. While the vertical synchronization signal VSYNC and the horizontal synchronization signal HSYNC are enabled to a low level in FIG. 4, they can be enabled to a high level.

The line counter 212 counts pulses of the horizontal synchronization signal HSYNC from time (A) when the vertical synchronization signal VSYND is enabled to a low level and outputs the line counting values CNT_LINE.

The first write enable signal generator 216 drives the pixel counter 214 when it receives a line counting value CNT_LINE corresponding to the VBP. For example, when the VBP corresponds to three cycles of the horizontal synchronization signal HSYNC, as shown in FIG. 4, the first write enable signal generator 216 drives the pixel counter 214 at time (B) when the line counting value CNT_LINE becomes 4. The pixel counter 214 counts pulses of the system clock signal DOTCLK from time (B) when the line counting value CNT_LINE corresponds to the VBP and outputs the counted result as the pixel counting values CNT_PIXEL.

The first write enable signal generator 216 generated the first write enable signal WCK_EN1 when it receives a pixel counting value CNT_PIXEL corresponding to the HBP. When the HBP corresponds to ten cycles of the system clock signal DOTCLK, for example, the first write enable signal generator 216 enables the first write enable signal WCK_EN1 from time (C) when the pixel counting value CNT_PIXEL becomes 11.

The first write enable signal generator 216 enables the first write enable signal WCK_EN1 during an effective data period DP. The first write enable signal generator 216 disables the first write enable signal WCK_EN1 in a period corresponding to vertical front porch (VFP).

For example, the first write enable signal generator 216 can generate the first write enable signal WCK_EN1 in the effective data period DP in which effective display data is received in response to the VBP, HBP and VFP. Accordingly, the source driver control device 200 according to an exemplary embodiment of the present invention can generate the first write enable signal WCK_EN1 though the first write controller 210 without receiving the first write enable signal WCK_EN1 from an external device.

As described above, the RGB sync interface is a device of controlling the source driver and does not provide the first write enable signal WCK_EN1. Thus, when the conventional source driver control device 100 is connected to the RGB sync interface, the first write enable signal WCK_should be supplied to the source driver control device 100 from an external device. However, the source driver control device 200 according to an exemplary embodiment of the present invention can generate the first write enable signal WCK_EN, from an external device even when the source driver control device signal WCK_EN1 from an external device even when the source driver control device 200 is connected to the RGB sync interface.

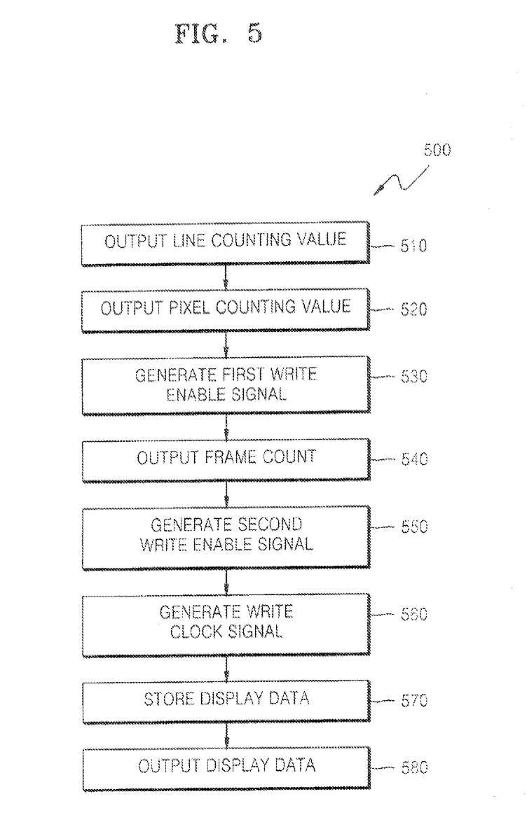

FIG. 5 is a flow chart showing a source driver control method 500 according to an exemplary embodiment of the present invention. Referring to FIG. 5, the source driver control method 500 includes a first write enable signal generating step 530, a second write enable signal generating step 550, a write clock signal generating step 560 and a display data storing step 570.

In the first write enable signal generating step 530, a first write enable signal is generated in response to VBP and HBP. In the second write enable signal generating step 550, a second write enable signal enabled for each write cycle corresponding to a multiple of a reference write cycle is generated in response to the first write enable signal. In the write clock signal generating step 560, a write clock signal is generated in a period in which the second write enable signal is enabled. In the display data storing step 570, display data is received and stored in response to the write clock signal. FIG. 5 also shows a display data output step 580. The display data output step 580 outputs the display data stored in the display data storing step 570 to an external device.

The source driver control method 500 according to an exemplary embodiment of the present invention can further include a line counting value output step 510 and a pixel counting value output step 520. In the line counting value output step 510, pulses of a horizontal synchronization signal are counted and the counted result is output as line counting values. In the pixel counting value output step 520, pulses of a system clock signal are counted and the counted result is output as pixel counting values. In this case, the first write enable signal generating step 530 enables the first write enable signal in response to a line counting value corresponding to the VBP and a pixel counting value corresponding to the HBP.

The source driver control method 500 according to the present invention can further include a frame count output step 540 in which pulses of a vertical synchronization signal are counted and the counted result is output as a frame count. In this case, the second write enable signal generating step 550 generates the second write enable signal in response to a write cycle select signal for selecting the write cycle and the frame count.

The source driver control method 500 according to an exemplary embodiment of the present invention has a similar purpose as the source driver control device 200 and corresponds to the operation of the source driver control device 200. As described above, the source driver control device and method according to exemplary embodiments of the present invention can generate a write enable signal to write display data in a memory without receiving the write enable signal from an external device.

Also, the source driver control device and method according to exemplary embodiments of the present invention can select a write cycle for storing display data in the memory, and thus reduce power consumption while writing display data.

While the present invention has been particularly shown and described with reference to exemplary embodiments thereof, it will be understood by those of ordinary skill in the art that various changes in form and details may be made therein without departing from the spirit and scope of the present invention.

1. A source driver control device comprising:
a memory receiving display data corresponding to an image and storing the display data in response to a write clock signal;
a first write controller generating first write enable signal in response to a vertical back porch and a horizontal back porch.
a second write controller generating a second write enable signal, which is enabled for each write cycle of storing the display data in the memory in response to the first write enable signal; and
a write clock signal generator generating the write clock signal in a period in which the second write enable signal is enabled,
wherein the write cycle corresponds to a multiple of the reference write cycle.

2. The source driver control device of claim 1, wherein the first write controller comprises:
a line counter counting pulses of a horizontal synchronization signal and outputting the counted result as line counting values;
a pixel counter counting pulses of a system clock signal and outputting the counted result as pixel counting values; and
a first write enable signal generator generating the first write enable signal in response to a line counting value corresponding to the vertical back porch and a pixel counting value corresponding to the horizontal back porch.

3. The source driver control device of claim 2, wherein the first write enable signal generator receives the line counting value corresponding to the vertical back porch, and then enables the first write enable signal upon receiving the pixel counting value corresponding to the horizontal back porch.

4. The source driver control device of claim 3, wherein the first write enable signal generator:
drives the pixel counter upon receiving the line counting value corresponding to the vertical back porch;
receives the pixel counting values from the pixel counter; and
enables the first write enable signal upon receiving the pixel counting value corresponding to the horizontal back porch.

5. The source driver control device of claim 4, wherein the first write enable signal generator holds the first write enable signal at the enabled level during an effective data period and disables the first write enable signal upon receiving a line counting value corresponding to a vertical front porch.

6. The source driver control device of claim 1, wherein the second write controller comprises:
a frame counter counting pulses of a vertical synchronization signal and outputting the counted result as a frame count; and
a second write enable signal generator generating the second write enable signal in response to a write cycle select signal for selecting the write cycle and the frame count.

7. The source driver control device of claim 6, wherein the second write enable signal generator generates the second write enable signal when receiving the frame count corresponding to the write cycle select signal.

8. The source driver control device of claim 1, further comprising a data converter receiving the display data and converting the display data into converted display data, the memory storing the converted display data.

9. The source driver control device of claim 1, wherein the reference write cycle corresponds to a time interval of a signal frame of the image and the write cycle corresponds to a time interval of at least one frame of the image.

10. The source driver control device of claim 9, wherein the write cycle is a time interval of a single frame, a time interval of two frames, or a time interval of four frames.

11. The source driver control device of claim 9, wherein the image includes a plurality of frame groups each including one or more frames, and the frames of each frame group have the same display data.

12. The source driver control device of claim 1, wherein the reference write cycle is 1/60 second and the write cycle is 1/15 second, 1/30 second, or 1/60 second.

13. The source driver control device of claim 1, wherein the source driver control device is operated in an RGB sync interface mode.

14. A source driver control device comprising:
a memory receiving display data corresponding to an image and storing the display data in response to a write clock signal; and
a memory controller generating the write clock signal for each write cycle of storing the display data in the memory,
wherein the write cycle corresponds to a multiple of a reference write cycle.

15. The source driver control device of claim 14, wherein the memory controller comprises:
a write enable signal generator generating a write enable signal, which is enabled for each write cycle, in response to a write cycle select signal for selecting the write cycle, and
a write clock signal generator generating the write clock signal in a period in which the write enable signal is enabled.

16. The source driver control device of claim 15, wherein the memory controller includes a frame counter counting pulses of a vertical synchronization signal and outputting the counted result as a frame count, and the write enable signal generator generates the write enable signal in response to the frame count and the write cycle select signal.

17. The source driver control device of claim 14, wherein the reference write cycle corresponds to a time interval of a single frame of the image and the write cycle corresponds to a time interval of at least one frame of the image.

18. The source driver control device of claim 14, wherein the reference write cycle is 1/60 second and the write cycle is 1/15 second, 1/30 second, or 1/60 second.

19. The source driver control device of claim 14, wherein the source driver control device is operated in an RGB sync interface mode.

20. A method of controlling a source driver comprising:
generating a first write enable signal in response to a vertical back porch and a horizontal back porch;
generating a second write enable signal, which is enabled for each write cycle corresponding to a multiple of a reference write cycle in response to the first write enable signal;
generating a write clock signal in a period in which the second write enable signal is enabled, and
receiving display data corresponding to an image and storing the display data in
receiving display data corresponding to an image and storing the display data in response to the write clock signal.

21. The method of claim 20, further comprising:
counting pulses of horizontal synchronization signal and outputting the counted result as line counting values; and
counting pulses of a system clock signal and outputting the counted result as pixel counting values,
wherein, in the generating the first write enable signal, the first write enable signal is enabled in response to a line counting value corresponding to the vertical back porch and a pixel counting value corresponding to the horizontal back porch.

22. The method of claim 21, wherein, in the generating the first write enable signal, the line counting value corresponding to the vertical back porch is received, and then the first write enable signal is enabled upon receiving the pixel counting value corresponding to the horizontal back porch.

23. The method of claim 22, wherein the pixel counting values are output when the line counting value corresponding to the vertical back porch is received in the generating the first write enable signal, and the first write enable signal is enabled upon receiving the pixel counting value corresponding to the horizontal back porch in the generating the first write enable signal.

24. The method of claim 23, wherein, in the generating the first write enable signal, the first write enable signal is enabled during an effective data period and the first write enable signal is disabled upon receiving a line counting value corresponding to a vertical front porch.

25. The method of claim 20, further comprising counting pulses of a vertical synchronization signal and outputting the counted result as a frame count, the second write signal being generated in response to a write cycle select signal for selecting the write cycle and the frame count in the generating the second write enable signal.

26. The method of claim 25, wherein, in the generating the second write enable signal, the second write enable signal is generated when a frame count corresponding to the write cycle select signal is received.
